(19) United States
(12) Patent Application Publication
(10) Pub. No.: US 2026/0058430 A1
(43) Pub. Date: Feb. 26, 2026

(54) LASER DEVICE AND ELECTRONIC DEVICE MANUFACTURING METHOD

(71) Applicant: GIGAPHOTON INC., Tochigi (JP)

(72) Inventor: Natsuhiko KOUNO, Tochigi (JP)

(73) Assignee: GIGAPHOTON INC., Tochigi (JP)

(21) Appl. No.: 19/379,083

(22) Filed: Nov. 4, 2025

Related U.S. Application Data
(63) Continuation of application No. PCT/JP2023/024467, filed on Jun. 30, 2023.

(51) Int. Cl. H01S 3/00; G03F 7/00; H01S 3/23

(52) U.S. Cl. CPC H01S 3/0057; G03F 7/70025; G03F 7/70041; G03F 7/7055; H01S 3/2308; H01S 3/2366

(57) ABSTRACT

A laser device includes an oscillator outputting pulse laser light; an amplifier amplifying the pulse laser light; an optical pulse stretcher extending a pulse width of the pulse laser light; a beam divergence angle adjuster including an upstream lens arranged on an optical path of the pulse laser light, a downstream lens arranged downstream of the upstream lens, and an optical path length changing mechanism for changing an inter-lens optical path length between the upstream lens and the downstream lens; and a processor controlling the beam divergence angle adjuster and obtaining a repetition frequency or a duty of the pulse laser light, and to change, when the repetition frequency or the duty changes by a preset threshold or more, the inter-lens optical path length so that the beam divergence angle of the extended pulse laser light becomes small in accordance with the repetition frequency or the duty after the change.

### CROSS-REFERENCE TO RELATED APPLICATIONS

The present application is a continuation application of International Application No. PCT/JP2023/024467, filed on Jun. 30, 2023, the entire contents of which are hereby incorporated by reference.

### BACKGROUND

### 1. Technical Field

The present disclosure relates to a laser device and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: Japanese Patent Application Publication No. 2008-168323

Patent Document 2: Japanese Patent Application Publication No. 2009-141186

### SUMMARY

A laser device according to an aspect of the present disclosure includes an oscillator configured to output pulse laser light having an ultraviolet wavelength; an amplifier configured to amplify the pulse laser light; an optical pulse stretcher including a beam splitter and a plurality of mirrors, and configured to extend a pulse width of the pulse laser light; a beam divergence angle adjuster including an upstream lens arranged upstream on an optical path of the pulse laser light, a downstream lens arranged downstream of the upstream lens on the optical path, and an optical path length changing mechanism for changing an inter-lens optical path length between the upstream lens and the downstream lens, and configured to adjust a beam divergence angle of the extended pulse laser light; and a processor configured to control the beam divergence angle adjuster and configured to obtain a repetition frequency or a duty of the pulse laser light, and to change, when the repetition frequency or the duty changes by a preset threshold or more, the inter-lens optical path length so that the beam divergence angle of the extended pulse laser light becomes small in accordance with the repetition frequency or the duty after the change.

An electronic device manufacturing method according to an aspect of the present disclosure includes outputting, to an exposure apparatus, pulse laser light output from a laser device; and exposing a photosensitive substrate to the pulse laser light in the exposure apparatus to manufacture an electronic device. Here, the laser device includes an oscillator configured to output the pulse laser light having an ultraviolet wavelength; an amplifier configured to amplify the pulse laser light; an optical pulse stretcher including a beam splitter and a plurality of mirrors, and configured to extend a pulse width of the pulse laser light; a beam divergence angle adjuster including an upstream lens arranged upstream on an optical path of the pulse laser light, a downstream lens arranged downstream of the upstream lens on the optical path, and an optical path length changing mechanism for changing an inter-lens optical path length between the upstream lens and the downstream lens, and configured to adjust a beam divergence angle of the extended pulse laser light; and a processor configured to control the beam divergence angle adjuster and configured to obtain a repetition frequency or a duty of the pulse laser light, and to change, when the repetition frequency or the duty changes by a preset threshold or more, the inter-lens optical path length so that the beam divergence angle of the extended pulse laser light becomes small in accordance with the repetition frequency or the duty after the change.

### BRIEF DESCRIPTION OF THE DRAWINGS

Embodiments of the present disclosure will be described below merely as examples with reference to the accompanying drawings.

FIG. 1 is a front view schematically showing a configuration example of a laser device according to a comparative example.

FIG. 2 is a top view schematically showing the configuration example of the laser device according to the comparative example.

FIG. 3 is an explanatory diagram of a beam divergence angle.

FIG. 4 is a diagram showing a sectional shape of a beam spot of the pulse laser light.

FIG. 5 is a front view schematically showing a configuration example of the laser device according to a first embodiment.

FIG. 6 is a top view schematically showing the configuration example of the laser device according to the first embodiment.

FIG. 7 is a diagram schematically showing a configuration example of a beam divergence angle adjuster.

FIG. 8 is a diagram schematically showing a configuration example of an optical path length changing mechanism.

FIG. 9 is a graph showing the relationship between an inter-lens optical path length and a beam divergence angle for each repetition frequency.

FIG. 10 is an example of table data used for control of beam divergence angle adjustment.

FIG. 11 is a flowchart showing a procedure of operation of the laser device according to the first embodiment.

FIG. 12 is a graph showing the relationship between the inter-lens optical path length and the beam divergence angle for each repetition frequency.

FIG. 13 is a diagram showing a state in which a concentration position of the pulse laser light and a focal point of a downstream lens coincide with each other.

FIG. 14 is a diagram showing a state in which the concentration position of the pulse laser light and the focal point coincide with each other due to changing the inter-lens optical path length.

FIG. 15 is an example of the table data used for control of the beam divergence angle adjustment in a second embodiment.

FIG. 16 is a flowchart showing a procedure of operation of the laser device according to the second embodiment.

FIG. 17 is a front view schematically showing a configuration example of the laser device according to a first modification.

FIG. 18 is a top view schematically showing the configuration example of the laser device according to the first modification.

FIG. 19 is a front view schematically showing a configuration example of the laser device according to a second modification.

FIG. 20 is a top view schematically showing the configuration example of the laser device according to the second modification.

FIG. 21 is a diagram showing a modification of the optical path length changing mechanism.

FIG. 22 is a diagram schematically showing a configuration example of an exposure apparatus.

### DESCRIPTION OF EMBODIMENTS

### <Contents>

1. Comparative example
1.1 Configuration
1.2 Operation
1.3 Problem
   2. First embodiment
2.1 Configuration
2.2 Operation
2.3 Effect
   3. Second embodiment
3.1 Configuration
3.2 Operation
3.3 Effect

### 4. Modification

4.1 First modification
4.2 Second modification
4.3 Other modification
   5. Electronic device manufacturing method

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

### 1.1 Configuration

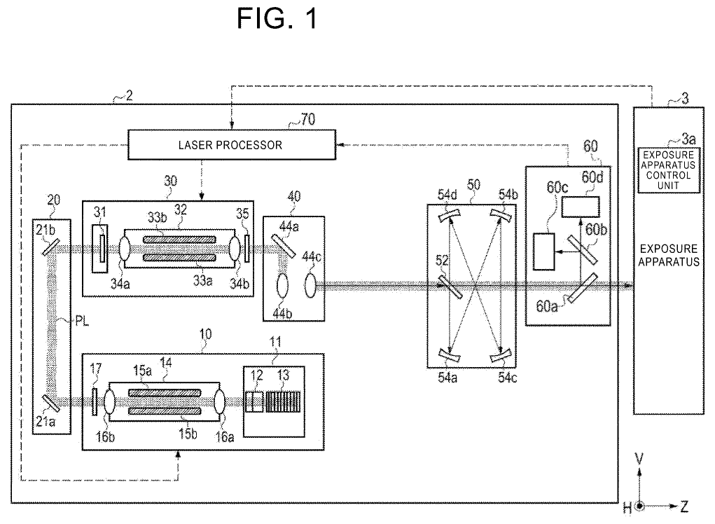

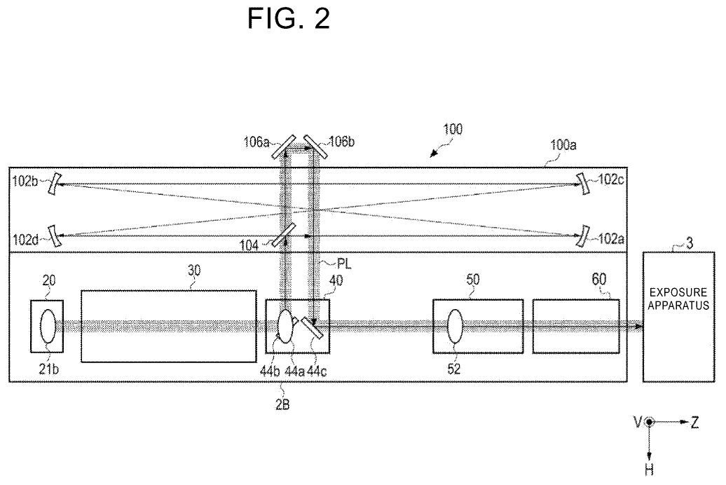

FIGS. 1 and 2 schematically show a configuration example of a laser device 2 according to a comparative example. The comparative example of the present disclosure is an example recognized by the applicant as known only by the applicant, and is not a publicly known example admitted by the applicant.

In FIGS. 1 and 2, the height direction of the laser device 2 is defined as a V-axis direction, the length direction thereof is defined as a Z-axis direction, and the depth direction thereof is defined as an H-axis direction.

The laser device 2 includes a master oscillator (MO) 10, an MO beam steering unit 20, a power oscillator (PO) 30, a PO beam steering unit 40, a first optical pulse stretcher (OPS) 100 (see FIG. 2), a second optical pulse stretcher (OPS) 50, a monitor module 60, and a laser processor 70. The laser device 2 is an excimer laser device for outputting pulse laser light PL that enters an exposure apparatus 3.

The master oscillator 10 includes a line narrowing module (LNM) 11, a chamber 14, and an output coupling mirror (Output Coupler: OC) 17. The master oscillator 10 is an example of the “oscillator that outputs pulse laser light having an ultraviolet wavelength” in the present disclosure.

The LNM 11 includes a prism beam expander 12 and a grating 13 for narrowing the spectral line width. The prism beam expander 12 and the grating 13 are arranged in the Littrow arrangement so that an incident angle and a diffraction angle coincide with each other.

The output coupling mirror 17 is a reflection mirror having a reflectance in the range of 40% to 60%. The output coupling mirror 17 and the LNM 11 are arranged to configure an optical resonator.

The chamber 14 is arranged on the optical path of the optical resonator. The chamber 14 includes a pair of discharge electrodes 15a, 15b and two windows 16a, 16b through which the pulse laser light PL passes. The chamber 14 accommodates an excimer laser gas. The excimer laser gas may include, for example, an Ar gas or a Kr gas as a rare gas, an F₂ gas as a halogen gas, and an Ne gas as a buffer gas.

The MO beam steering unit 20 includes a high reflection mirror 21a and a high reflection mirror 21b. The high reflection mirror 21a and the high reflection mirror 21b are arranged such that the pulse laser light PL output from the master oscillator 10 enters the power oscillator 30. The high reflection mirror of the present disclosure is a planar mirror with a high reflection film formed on a surface of a substrate formed of, for example, synthetic quartz or calcium fluoride (CaF₂). The high reflection film is a dielectric multilayer film, for example, a film containing fluoride.

The power oscillator 30 includes a rear mirror 31, a chamber 32, and an output coupling mirror 35. The rear mirror 31 and the output coupling mirror 35 are arranged to configure an optical resonator. The power oscillator 30 is an example of the “amplifier that amplifies pulse laser light”in the present disclosure.

The chamber 32 is arranged on the optical path of the optical resonator. The chamber 32 may have a configuration similar to that of the chamber 14 of the master oscillator 10. That is, the chamber 32 includes a pair of discharge electrodes 33a, 33b and two windows 34a, 34b through which the pulse laser light PL passes. The chamber 32 accommodates an excimer laser gas.

The rear mirror 31 is a reflection mirror having a reflectance in the range of 50% to 90%. The output coupling mirror 35 is a reflection mirror having a reflectance in the range of 10% to 30%.

The PO beam steering unit 40 includes a high reflection mirror 44a, a high reflection mirror 44b, and a high reflection mirror 44c. The high reflection mirror 44a and the high reflection mirror 44b are arranged such that the pulse laser light PL output from the power oscillator 30 enters the first OPS 50. The high reflection mirror 44c is arranged such that the pulse laser light PL output from the first OPS 100 is reflected to enter the second OPS 50.

The first OPS 100 is an optical pulse stretcher having a large delay optical path to produce a long optical path difference to extend the pulse width as compared to the second OPS 50. The first OPS 100 is arranged on the back surface of the laser device 2. The “back surface” is on the back side when viewed from the front side of the laser device 2.

The first OPS 100 includes a beam splitter 104, four concave mirrors 102a to 102d, and a housing 100a that accommodates the beam splitter 104 and the concave mirrors 102a to 102d.

The beam splitter 104 is arranged on the optical path of the pulse laser light PL output from the PO beam steering unit 40. The beam splitter 104 is a reflection mirror that transmits a part of the pulse laser light PL of the incident pulse laser light PL and reflects the other part thereof. The reflectance of the beam splitter 104 is preferably in the range of 40% to 70%, more preferably about 60%. The beam splitter 104 causes the pulse laser light PL transmitted through the beam splitter 104 to be output toward the high reflection mirror 106a.

The high reflection mirror 106a and the high reflection mirror 106b are arranged such that the pulse laser light PL extended by the first OPS 100 re-enters the PO beam steering unit 40.

The four concave mirrors 102a to 102d configure a delay optical path of the pulse laser light PL reflected by a first surface of the beam splitter 104. The pulse laser light PL reflected by the first surface of the beam splitter 104 is reflected by the four concave mirrors 102a to 102d, and the beam is focused again on the beam splitter 104.

The four concave mirrors 102a to 102d may be concave mirrors all having substantially the same focal length. A focal length f of each of the concave mirrors 102a to 102d may correspond to, for example, the distance from the beam splitter 104 to the concave mirror 102a.

The concave mirror 102a and the concave mirror 102b are arranged such that the pulse laser light PL reflected by the first surface of the beam splitter 104 is reflected by the concave mirror 102a to be incident on the concave mirror 102b. The concave mirror 102a and the concave mirror 102b are arranged such that the pulse laser light PL reflected by the first surface of the beam splitter 104 is focused as a first image at equal magnification (1: 1) on the first surface of the beam splitter 104.

The concave mirror 102c and the concave mirror 102d are arranged such that the pulse laser light PL reflected by the concave mirror 102b is reflected by the concave mirror 102c to be incident on the concave mirror 102d. Further, the concave mirror 102d is arranged such that the pulse laser light PL reflected by the concave mirror 102d is incident on a second surface of the beam splitter 104 on the side opposite to the first surface. The concave mirror 102c and the concave mirror 102d are arranged such that the first image is focused on the second surface of the beam splitter 104 at 1:1 as a second image.

The first OPS 100 is exemplified as having the four concave mirrors 102a to 102d, but may actually have concave mirrors in the range of 16 to 34. Further, the delay optical path length of the first OPS 100 is, for example, within 30 to 75 meters.

The second OPS 50 is substantially the same as the configuration of the first OPS 100 except that the delay optical path length is relatively short. The second OPS 50 includes a beam splitter 52 and four concave mirrors 54a to 54d. The beam splitter 52 is arranged on the optical path of the pulse laser light PL output from the PO beam steering unit 40. The beam splitter 52 is a reflection mirror that transmits a part of the pulse laser light PL of the incident pulse laser light PL and reflects the other part thereof. The reflectance of the beam splitter 52 is preferably in the range of 40% to 70%, more preferably about 60%. The beam splitter 52 causes the pulse laser light PL transmitted through the beam splitter 52 to be output from the laser device 2.

The four concave mirrors 54a to 54d form a delay optical path of the pulse laser light PL reflected by a first surface of the beam splitter 52. The pulse laser light PL reflected by the first surface of the beam splitter 52 is reflected by the four concave mirrors 54a to 54d, and the beam is focused again on the beam splitter 52.

The four concave mirrors 54a to 54d may be concave mirrors all having substantially the same focal length. The focal length f of each of the concave mirrors 54a to 54d may correspond to, for example, the distance from the beam splitter 52 to the concave mirror 54a.

The concave mirror 54a and the concave mirror 54b are arranged such that the pulse laser light PL reflected by the first surface of the beam splitter 52 is reflected by the concave mirror 54a to be incident on the concave mirror 54b. The concave mirror 54a and the concave mirror 54b are arranged such that the pulse laser light PL reflected by the first surface of the beam splitter 52 is focused as a first image at equal magnification (1:1) on the first surface of the beam splitter 52.

The concave mirror 54c and the concave mirror 54d are arranged such that the pulse laser light PL reflected by the concave mirror 54b is reflected by the concave mirror 54c to be incident on the concave mirror 54d. Further, the concave mirror 54d is arranged such that the pulse laser light PL reflected by the concave mirror 54d is incident on a second surface of the beam splitter 52 on the side opposite to the first surface. The concave mirror 54c and the concave mirror 54d are arranged such that the first image is focused on the second surface of the beam splitter 52 at 1:1 as a second image.

The second OPS 50 is exemplified as having the four concave mirrors 54a to 54d, but may actually have concave mirrors in the range of 4 to 12. Further, the delay optical path length of the second OPS 50 is, for example, within 5 to 25 meters.

The monitor module 60 includes beam splitters 60a, 60b, a pulse energy measurement device 60c, and a spectrum measurement device 60d. The beam splitter 60a is arranged on the optical path of the pulse laser light PL output from the second OPS 50, and reflects a part of the pulse laser light PL and transmits another part thereof. The pulse laser light PL transmitted through the beam splitter 60a enters the exposure apparatus 3.

The beam splitter 60b is arranged on the optical path of the pulse laser light PL reflected by the beam splitter 60a. The pulse energy measurement device 60c is arranged on the optical path of the pulse laser light PL reflected by the beam splitter 60b, and measures the pulse energy of the pulse laser light PL. The spectrum measurement device 60d is arranged on the optical path of the pulse laser light PL transmitted through the beam splitter 60b, and measures the spectrum of the pulse laser light PL. The measurement data of the pulse energy and the measurement data of the spectrum are transmitted to the laser processor 70.

The laser processor 70 is communicably connected to an exposure apparatus control unit 3a of the exposure apparatus 3 via a signal line. The laser processor 70 receives a signal from the exposure apparatus control unit 3a. The signal received by the laser processor 70 includes a target pulse energy, a target wavelength, a target spectral line width, and a light emission trigger signal.

The exposure apparatus 3 is an apparatus that performs exposure on a photosensitive substrate such as a semiconductor wafer (not shown) using the pulse laser light PL.

### 1.2 Operation

The laser processor 70 of the laser device 2 receives the target pulse energy, the target wavelength, the target spectral line width, and the light emission trigger signal from the exposure apparatus control unit 3a. The light emission trigger signal is transmitted from the exposure apparatus control unit 3a to the laser processor 70 at a repetition frequency corresponding to the operation of the exposure apparatus 3.

The laser processor 70 applies a high voltage between the discharge electrodes 15a, 15b of the master oscillator 10 in synchronization with the light emission trigger signal. When discharge occurs in the chamber 14 of the master oscillator 10, the laser gas is excited, and laser oscillation is started by the optical resonator configured by the output coupling mirror 17 and the LNM 11. When laser oscillation is started, the line-narrowed pulse laser light PL whose center wavelength is an ultraviolet wavelength in a range from 150 to 380 nm is output from the output coupling mirror 17. The pulse laser light PL is incident on the rear mirror 31 of the power oscillator 30 as seed light by the MO beam steering unit 20.

Discharge occurs in the chamber 32 in synchronization with the timing when the seed light transmitted through the rear mirror 31 enters. As a result, the laser gas is excited, the seed light is amplified by the Fabry-Perot optical resonator configured by the output coupling mirror 35 and the rear mirror 31, and the amplified pulse laser light PL is output from the output coupling mirror 35. The pulse laser light PL output from the output coupling mirror 35 enters the first OPS 100 via the PO beam steering unit 40.

A part of the pulse laser light PL having entered the first OPS 100 is transmitted through the beam splitter 104 and is output, and another part thereof is reflected by the beam splitter 104. The pulse laser light PL reflected by the beam splitter 104 circulates through the delay optical path formed by the first to fourth concave mirrors 102a to 102d and is incident on the beam splitter 104 again. Then, a part of the pulse laser light PL incident on the beam splitter 104 is reflected and output from the first OPS 100. The pulse laser light PL transmitted through the beam splitter 104 circulates through the delay optical path.

As described above, owing to that the pulse laser light PL repeatedly circulates through the delay optical path, the pulse laser light PL of zero-circulation light, that of one-circulation light, that of two-circulation light, that of three-circulation light, . . . are output from the first OPS 100. The light intensity of the pulse laser light PL output from the first OPS 100 decreases as the number of circulations in the delay optical path increases.

The pulse laser light PL of one-circulation light and that thereafter are delayed each by an integer multiple of the delay time, determined by the optical path length of the delay optical path, with respect to the pulse laser light PL of zero-circulation light and are combined and output. That is, the pulse waveform of the pulse laser light PL of one-circulation light and that thereafter is sequentially superimposed on the pulse waveform of the pulse laser light PL of the zero-circulation light, while being delayed by the delay times, respectively. Thus, the pulse width of the pulse laser light PL is extended by the first OPS 100.

By extending the pulse width of the pulse laser light PL by the first OPS 100, the coherence is reduced. This suppresses occurrence of speckle. Speckle is light and dark spots caused by interference when laser light is scattered in a random medium.

The pulse laser light PL whose pulse width is extended by the first OPS 100 enters the second OPS 50 via the PO beam steering unit 40. In the second OPS 50 as well, the pulse laser light PL is extended through the similar action as in the first OPS 100.

The pulse laser light PL whose pulse width is extended by the second OPS 50 enters the monitor module 60. A part of the pulse laser light PL having entered the monitor module 60 is reflected by the beam splitter 60a. A part of the pulse laser light PL reflected by the beam splitter 60a is reflected by the beam splitter 60b and enters the pulse energy measurement device 60c, so that the pulse energy is measured. Further, a part of the pulse laser light PL reflected by the beam splitter 60a is transmitted through the beam splitter 60b and enters the spectrum measurement device 60d, so that the spectrum is measured.

The laser processor 70 controls the voltage applied to the pair of discharge electrodes 33a, 33b of the power oscillator 30 so that the difference between the target pulse energy and the measured pulse energy approaches zero.

The laser processor 70 calculates the wavelength from the measured spectrum, and controls the angle of the prism beam expander 12 of the LNM 11 so that the wavelength of the pulse laser light PL output from the laser device 2 becomes the target wavelength. Further, the laser processor 70 calculates the spectral line width from the measured spectrum, and controls a wavefront adjuster (not shown) so that the spectral line width of the pulse laser light PL output from the laser device 2 becomes the target spectral line width.

The pulse laser light PL output from the laser device 2 enters the exposure apparatus 3 and is radiated to a photosensitive substrate such as a semiconductor wafer (not shown).

### 1.3 Problem

The repetition frequency or duty determined in accordance with the cycle of the light emission trigger signal transmitted from the exposure apparatus 3 may change in accordance with the operation state of the exposure apparatus 3. When the repetition frequency or the duty is changed, thermal deformation or the like occurs in the optical element, and the beam divergence angle of the pulse laser light PL is changed due to the thermal deformation or the like. When the beam divergence angle increases, vignetting or the like of a beam occurs in the exposure apparatus 3, and loss of the energy of the pulse laser light PL occurs. The change in the beam divergence angle is larger when the pulse laser light PL is extended using the optical pulse stretcher than without using the optical pulse stretcher, for example. In particular, the change in the beam divergence angle becomes more pronounced as an optical pulse stretcher has more optical elements such as concave mirrors, and more pronounced as an optical pulse stretcher has a longer delay optical path length as the first OPS 100 shown in the comparative example.

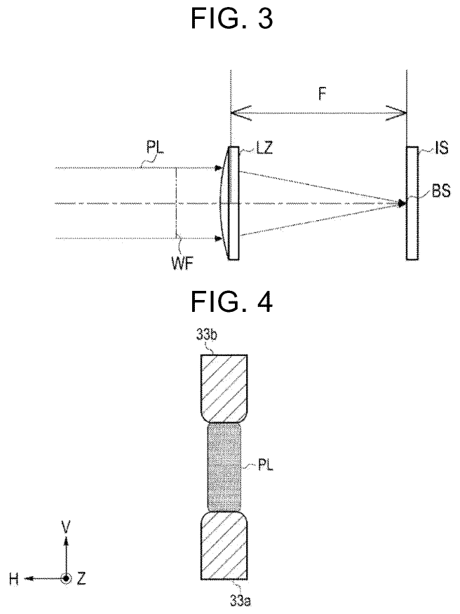

Here, as shown in FIG. 3, the pulse laser light PL is concentrated by a light concentrating lens LZ, and the beam divergence angle is defined as a value obtained by dividing the size of a beam spot BS at the position of a focal length F of the light concentrating lens LZ by the focal length F. The size of the beam spot BS is the diameter or full width. The size of the beam spot BS is measured by a two-dimensional image sensor IS arranged at the position of the focal length F. As the pulse laser light PL shown in FIG. 3, when the wavefront is a plane WF0, the concentration position of the pulse laser light PL by the light concentrating lens LZ and the focal point corresponding to the focal length F of the light concentrating lens LZ coincide with each other, the size of the beam spot BS to be imaged at the focal point is minimized, and the beam divergence angle is also minimized.

On the other hand, when the pulse laser light PL is divergent and the wavefront becomes a convexly curved surface toward the light concentrating lens LZ, the concentration position of the pulse laser light PL concentrated by the light concentrating lens LZ is located downstream of the focal point. In this case, the size of the beam spot BS measured by the two-dimensional image sensor IS increases, and the beam divergence angle also increases.

The duty is a value corresponding to the cycle of the plurality of light emission trigger signals repeatedly output by the exposure apparatus 3. A duty DC is defined by Expression (1) below.

Dc(%)=(np/np_max)×100 (1)

Here, Np is the number of pulses oscillated within a preset set time Tc after laser oscillation is started. Np_max is the product of a maximum repetition frequency RR_max determined according to the performance of the laser device 2 and a set time Tc, and is the maximum number of pulses that the laser device 2 can output within the set time Tc. That is, the duty DC indicates the ratio of the number of pulses actually output to the maximum number of pulses that the laser device 2 can output within a unit time.

Further, as shown in FIG. 4, the sectional shape of the beam spot BS of the pulse laser light PL is a substantially rectangular shape in which the discharge direction (V-axis direction) is a long side. Therefore, the beam divergence angles in the discharge direction and in the direction (H-axis direction) perpendicular to the discharge direction are different from each other, and the beam divergence angle in the discharge direction is larger.

### 2. First Embodiment

### 2.1 Configuration

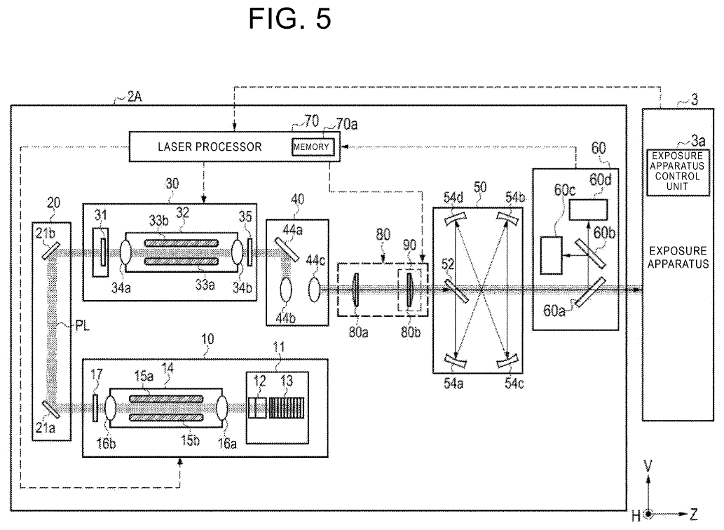

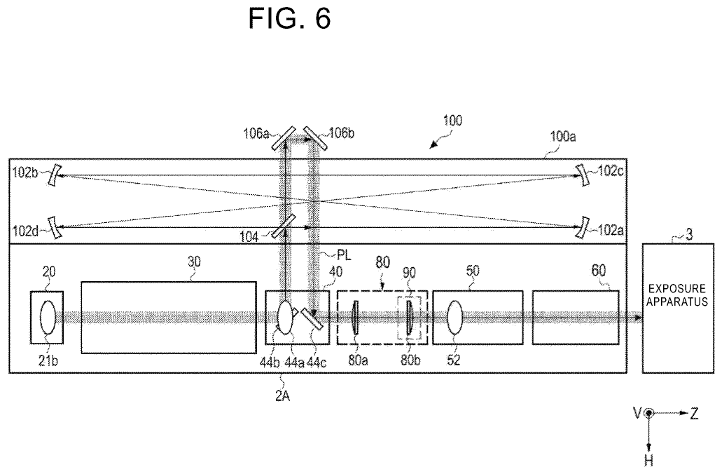

FIGS. 5 and 6 schematically show a configuration example of a laser device 2A according to a first embodiment of the present disclosure. The laser device 2A shown in FIGS. 5 and 6 will be described in terms of differences from the configuration of the laser device 2 according to the comparative example shown in FIGS. 1 and 2. The laser device 2A according to the first embodiment is different from the configuration of the laser device 2 according to the comparative example in that a beam divergence angle adjuster 80 is included and that the laser processor 70 has a function of controlling the beam divergence angle adjuster 80.

As shown in FIGS. 5 and 6, the beam divergence angle adjuster 80 is arranged between the first OPS 100 and the second OPS 50 on the optical path of the pulse laser light PL. The first OPS 100 is an example of the “optical pulse stretcher” or the “first optical pulse stretcher” in the present disclosure, and the second OPS 50 is an example of the “second optical pulse stretcher” in the present disclosure.

The beam divergence angle adjuster 80 includes an upstream lens 80a arranged upstream on the optical path of the pulse laser light PL, a downstream lens 80b arranged downstream of the upstream lens 80a, and an optical path length changing mechanism 90 for changing an inter-lens optical path length L between the upstream lens 80a and the downstream lens 80b, and adjusts the beam divergence angle of the extended pulse laser light PL.

The laser processor 70 obtains a repetition frequency RR of the pulse laser light PL, and when the repetition frequency RR changes by a preset first threshold Th1 or more, changes the inter-lens optical path length L so that the beam divergence angle of the extended pulse laser light PL becomes small in accordance with the repetition frequency RR after the change. The laser processor 70 is an example of the “processor” in the present disclosure. The laser processor 70 is provided with a memory 70a. The memory 70a stores reference information that is referred to by the laser processor 70 to adjust the beam divergence angle. The reference information will be described later.

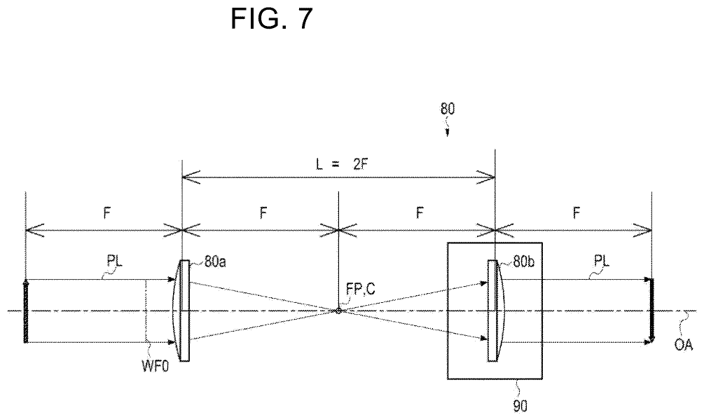

As shown in FIG. 7, in the beam divergence angle adjuster 80, the upstream lens 80a and the downstream lens 80b function as a relay lens that relays, via the downstream lens 80b, the beam spot BS of the pulse laser light PL concentrated by the upstream lens 80a. The upstream lens 80a is a plano-convex lens having a convex spherical surface on the incident side of the pulse laser light PL and a planar surface on the output side thereof, and the downstream lens 80b is a plano-convex lens having a planar surface on the incident side thereof and a convex spherical surface on the output side thereof, as shown as an example. Cross-sections of the upstream lens 80a and the downstream lens 80b in a direction perpendicular to an optical axis OA thereof are circular.

Further, for example, the focal lengths F of the upstream lens 80a and the downstream lens 80b are the same. The focal lengths of the upstream lens 80a and the downstream lens 80b are, for example, in a range of 500 to 1000 mm.

In the initial state, the upstream lens 80a and the downstream lens 80b are arranged such that a downstream-side focal point FP of the upstream lens 80a and an upstream-side focal point FP of the downstream lens 80b coincide with each other. That is, in the initial state, the inter-lens optical path length L between the upstream lens 80a and the downstream lens 80b is 2F being twice the focal length F. When the pulse laser light PL whose wavefront is the plane WF0 is incident on the upstream lens 80a arranged as described above, the focal point FP of the upstream lens 80a and a concentration position C of the pulse laser light PL coincide with each other, and the beam divergence angle at the focal point FP is minimized. Further, by setting the inter-lens optical path length L at twice the focal length F of the upstream lens 80a and the downstream lens 80b as described above, the image of the pulse laser light PL at the upstream-side focal point of the upstream lens 80a is formed at the downstream-side focal point of the downstream lens 80b at equal magnification (1:1). The image of the pulse laser light PL before being incident on the upstream lens 80a and the image after being output from the downstream lens 80b are reversed in both vertical and lateral directions.

As an example, the downstream lens 80b is movable along the optical axis OA by the optical path length changing mechanism 90, and the optical path length changing mechanism 90 changes the inter-lens optical path length L by changing the position of the downstream lens 80b.

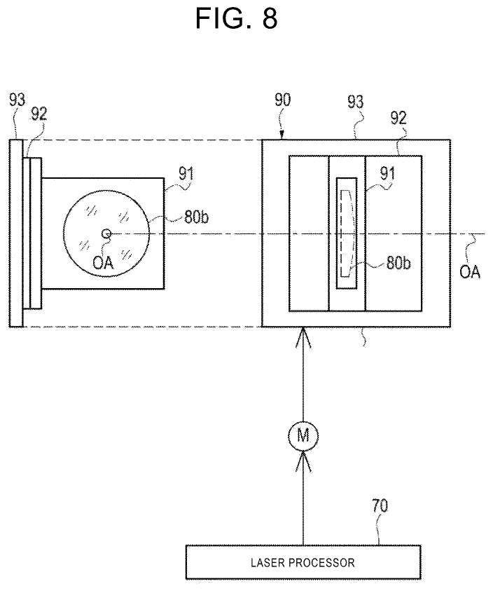

As shown in FIG. 8, the optical path length changing mechanism 90 includes a lens holder 91 that holds the downstream lens 80b, a linear stage 92, and a pedestal 93. The pedestal 93 fixes the linear stage 92. The linear stage 92 moves the lens holder 91 in the direction of the optical axis OA. The linear stage 92 is driven by a motor M. The laser processor 70 changes the position of the downstream lens 80b in the direction of the optical axis OA by moving the linear stage 92 using the motor M. Instead of the linear stage 92, a mechanism for pushing and pulling the lens holder 91 in the direction of the optical axis OA using an actuator may be provided.

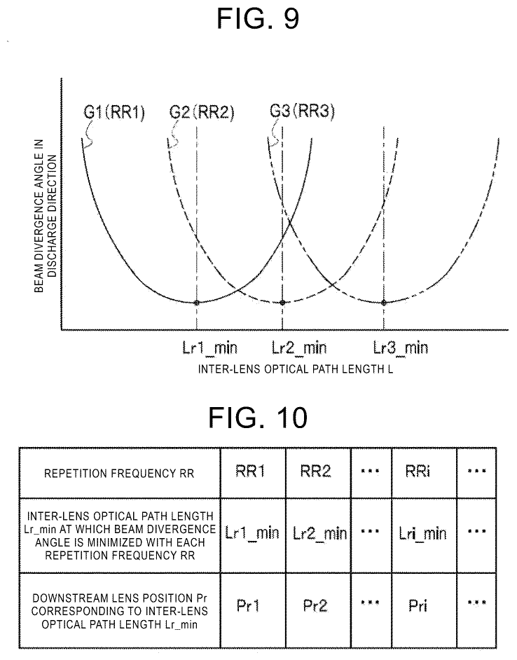

As shown in FIG. 9, the inter-lens optical path length L and the beam divergence angle in the discharge direction are in a downward parabola-like relationship for each repetition frequency RR. Each graph of FIG. 9 can be obtained for each repetition frequency RR by obtaining, by simulation or experiment, the beam divergence angle when the inter-lens optical path length L is changed.

In graph G1 for a repetition frequency RR1, the inter-lens optical path length L at the minimum point at which the beam divergence angle is minimized is Lr1_min. Decreasing or increasing the inter-lens optical path length L with respect to Lr1_min means moving the position of the downstream lens 80b back and forth in the direction of the optical axis OA. Since the position at which the beam divergence angle is minimized is determined to one point, when the inter-lens optical path length L is changed by moving the downstream lens 80b back and forth from the position, the beam divergence angle increases. Therefore, the inter-lens optical path length L and the beam divergence angle in the discharge direction are in the downward parabola-like relationship.

In graph G2 for a repetition frequency RR2, the inter-lens optical path length L at the minimum point at which the beam divergence angle is minimized is Lr2_min. In graph G3 for a repetition frequency RR3, the inter-lens optical path length L at the minimum point at which the beam divergence angle is minimized is Lr3_min. The magnitude relationship among the repetition frequencies RR1 to RR3 is such that the repetition frequency RR1 is minimum, the repetition frequency RR3 is maximum, and the repetition frequency RR2 is intermediate. According to the graphs shown in FIG. 9, the inter-lens optical path lengths Lr1_min to Lr3_min at which the beam divergence angles of the respective repetition frequencies RR1 to RR3 are minimized tend to increase as the repetition frequency RR increases. This is presumed to be because the larger the repetition frequency RR is, the larger the thermal deformation of the optical element becomes, and accordingly the beam divergence angle increases.

Based on the relationship between the beam divergence angle and the inter-lens optical path length L, the laser processor 70 controls the inter-lens optical path length L so that the beam divergence angle becomes smaller when the repetition frequency RR changes.

FIG. 10 shows table data generated based on the relationship shown in FIG. 9. The table data shown in FIG. 10 is information recorded by associating each of the plurality of repetition frequencies RR with the inter-lens optical path length Lr_min at which the beam divergence angle of the extended pulse laser light PL is minimized. In the data table shown in FIG. 10, a downstream lens position Pr corresponding to the inter-lens optical path lengths Lr_min is also recorded. Each of the inter-lens optical path length Lr_min and the downstream lens position Pr is an example of the “information related to the inter-lens optical path length” in the present disclosure. The interval between the plurality of repetition frequencies RR recorded in the table data is, for example, in a range of 100 to 500 Hz.

The memory 70a of the laser processor 70 stores the table data shown in FIG. 10 as reference information. In the table data, one of the inter-lens optical path length Lr_min and the downstream lens position Pr may be stored, and the other may be calculated from a value of the one. Further, since the laser processor 70 is finally controlled based on the downstream lens position Pr, the information stored in the memory 70a may be only the downstream lens position Pr for each repetition frequency RR.

Further, as described above, the beam divergence angle of the pulse laser light PL is larger in the discharge direction than in the direction perpendicular to the discharge direction. In the control of the beam divergence angle, it is often necessary to control the discharge direction in which the beam divergence angle is relatively large. The laser processor 70 controls the inter-lens optical path length L based on the data in the discharge direction in which the beam divergence angle is relatively large. The beam divergence angle, which is the basis of the graph shown in FIG. 9 and the table data shown in FIG. 10, is data in the discharge direction. That is, in the control of the beam divergence angle adjuster 80, the laser processor 70 controls the inter-lens optical path length L based on the beam divergence angle in the discharge direction of the discharge electrodes 33a, 33b.

Naturally, since the cross-sections of the upstream lens 80a and the downstream lens 80b are circular, the beam divergence angle is adjusted not only in the discharge direction but also in the direction perpendicular to the discharge direction. However, with emphasis on the beam divergence angle in the discharge direction, the laser processor 70 controls the inter-lens optical path length L so that the beam divergence angle in the discharge direction is minimized.

### 2.2 Operation

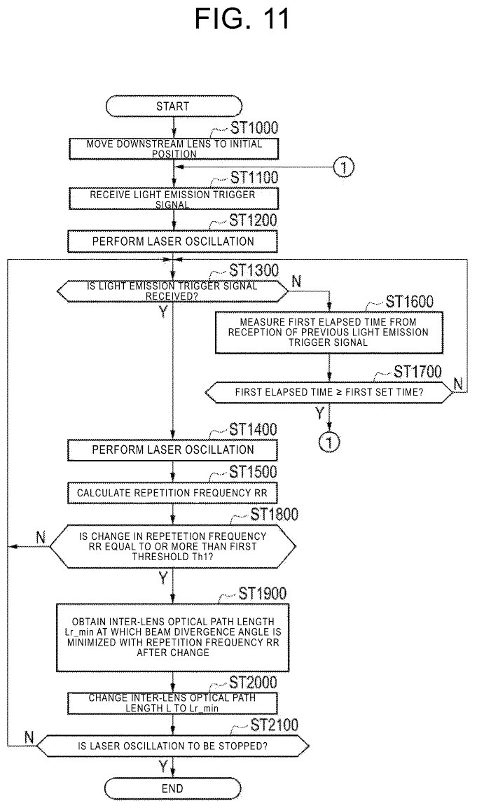

Operation of the laser device 2A will be described as referring to a flowchart shown in FIG. 11. When the control of the beam divergence angle is started, the laser processor 70 first moves the downstream lens 80b to a preset initial position in step ST1000. As shown in FIG. 7 as an example, the initial position is a position where the inter-lens optical path length L is twice the focal length F (2F).

In step ST1100, when the light emission trigger signal is received from the exposure apparatus 3, the laser processor 70 proceeds to step ST1200 and starts laser oscillation of the laser device 2A. After laser oscillation is started, in step ST1300, the laser processor 70 waits for reception of a subsequent light emission trigger signal.

In step ST1300, when the subsequent light emission trigger signal is received (Y in step ST1300), processing proceeds to step ST1400, and the laser processor 70 starts laser oscillation.

Then, in step ST1500, the laser processor 70 calculates the repetition frequency RR based on the time interval between two consecutively received light emission trigger signals.

On the other hand, in step ST1300, while waiting for reception of the subsequent light emission trigger signal (N in step ST1300), in step ST1600, the laser processor 70 measures a first elapsed time from the reception of the previous light emission trigger signal. Then, in step ST1700, the laser processor 70 determines whether or not the first elapsed time is equal to or more than a first set time, returns to step ST1300 while the first elapsed time is less than the first set time (N in step ST1700), and waits for reception of the subsequent light emission trigger signal.

In step ST1700, when the first elapsed time has reached the first set time or more (Y in step ST1700), the laser processor 70 returns to step ST1100. The reason therefor is as follows. In step ST1500, the repetition frequency RR is calculated based on the time interval between two consecutively received light emission trigger signals. However, depending on the operation state of the exposure apparatus 3, there may be a period in which the exposure is paused, and in this case, the light emission trigger signal may not be received for a relatively long time. When the time interval of the two consecutively received light emission trigger signals is the first set time or more, since it is not suitable as a time interval for calculating the repetition frequency RR, in that case, it is considered preferable to re-measure, without calculating the repetition frequency RR, the first elapsed time from the reception of the first light emission trigger signal. Therefore, when the first elapsed time has reached the first set time or more, the first elapsed time is measured again. The first set time is, for example, in the range of 1 to 10 seconds.

After calculating the repetition frequency RR in step ST1500, the laser processor 70 proceeds to step ST1800. In step ST1800, the laser processor 70 determines whether or not the change in the repetition frequency RR is equal to or more than the first threshold Th1. When the determination result is being less than the first threshold Th1 (N in step ST1800), the laser processor 70 returns to step ST1300, and when the determination result is being equal to or more than the first threshold Th1 (Y in step ST1800), the laser processor 70 proceeds to step ST1900.

The reason for setting the first threshold Th1 is that, when the change is very small, there may be a case in which necessity of changing the inter-lens optical path length L is low. Therefore, by setting the first threshold Th1, when the change in the repetition frequency RR is less than the first threshold Th1, it is set as a dead zone in which the inter-lens optical path length L is not to be changed. As the first threshold Th1, a value that is considered to be appropriate as a reference for the dead zone is set in advance. Even when the change is slight, there may be a case in which it is desirable to change the inter-lens optical path length L. Therefore, the first threshold Th1 is set to a value, for example, in a range of 0 to 200 Hz. In order to substantially provide the dead zone, the first threshold Th1 is preferably set to a value larger than 0 Hz. The first threshold Th1 is an example of the “threshold”in the present disclosure.

In step ST1900, the laser processor 70 refers to the table data (see FIG. 10) stored in the memory 70a to obtain the inter-lens optical path length Lr_min at which the beam divergence angle is minimized with the repetition frequency RR after the change.

In step ST2000, the laser processor 70 changes the inter-lens optical path length L to the obtained inter-lens optical path length Lr_min. Specifically, the laser processor 70 reads the downstream lens position Pr corresponding to the obtained inter-lens optical path length Lr_min from the table data in the memory 70a. Then, the downstream lens 80b is moved to the read downstream lens position Pr by controlling the optical path length changing mechanism 90. As a result, the inter-lens optical path length L is changed to “Lr_min”.

The laser processor 70 continues the above operation until laser oscillation is stopped (step ST2100).

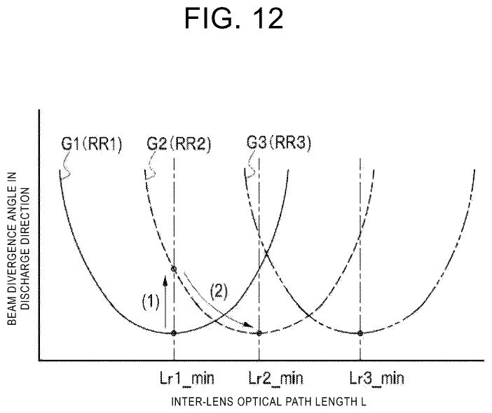

The control of the beam divergence angle adjustment will be described in more detail with reference to FIGS. 12 to 14. For example, consideration is provided on a case that the repetition frequency RR before the change is “RR1” and the repetition frequency RR changes to “RR2”. As shown in FIG. 12, first, since the repetition frequency RR before the change is “RR1”, the inter-lens optical path length Lr_min at which the beam divergence angle is minimized is “Lr1_min”. The position of the downstream lens 80b is also set to “Pr1” corresponding thereto.

When the repetition frequency RR changes to “RR2”, as indicated by arrow (1) in FIG. 12, the beam divergence angle increases when the inter-lens optical path length L remains “Lr1_min” with “RR2”. Therefore, the laser processor 70 changes the inter-lens optical path length L to the inter-lens optical path length Lr2_min at which the beam divergence angle is minimized with “RR2” which is the repetition frequency RR after the change, as indicated by arrow (2) in FIG. 12. The inter-lens optical path length L is changed by changing the position of the downstream lens 80b to “Pr2”.

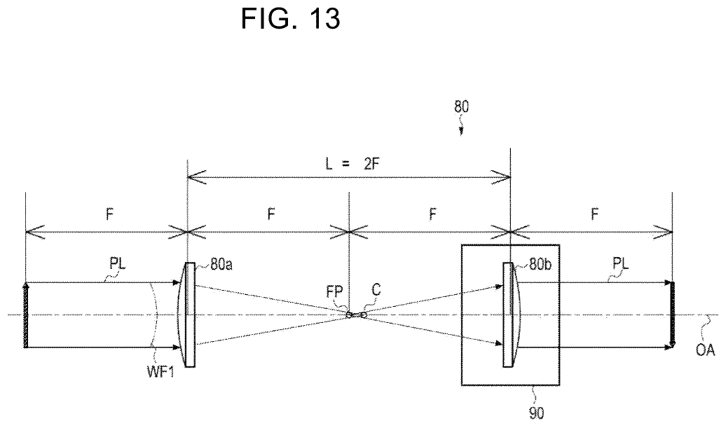

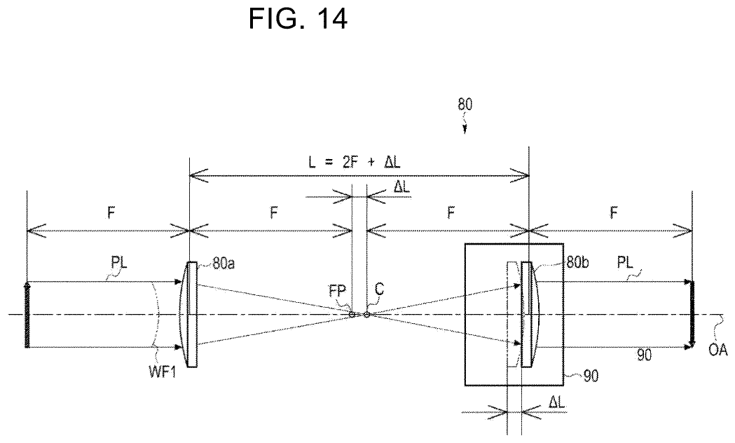

With reference to FIGS. 13 and 14, the change in the concentration position C of the pulse laser light PL by the upstream lens 80a in accordance with the change in the repetition frequency RR and the meaning of changing the position of the downstream lens 80b will be schematically described as in FIG. 7. First, the inter-lens optical path length L between the upstream lens 80a and the downstream lens 80b shown in FIG. 13 is “2F” which is twice the focal length F similar to the initial state shown in FIG. 7. In this state, if there is no thermal deformation or the like, as shown in FIG. 7, since the wavefront of the pulse laser light PL incident on the upstream lens 80a is the plane WF0, the concentration position C of the pulse laser light PL coincides with the focal point FP of the upstream lens 80a.

However, when the repetition frequency RR changes, as shown in FIG. 13, the wavefront of the pulse laser light PL becomes a curved surface WF1 convexed toward the downstream side due to thermal deformation or the like of the optical element, and the concentration position C of the pulse laser light PL moves to the downstream side with respect to the focal point FP of the upstream lens 80a. Since the beam divergence angle of the pulse laser light PL is minimized at the concentration position C, when the concentration position C deviates from the focal point FP, the beam divergence angle at the focal point FP increases. In the state shown in FIG. 13, since the position of the downstream lens 80b is not changed, the upstream-side focal point of the downstream lens 80b is in a state of coinciding with the focal point FP of the upstream lens 80a, and the downstream lens 80b relays an image having a large beam divergence angle.

Therefore, when the concentration position C is moved as shown in FIG. 13, as shown in FIG. 14, the downstream lens 80b is moved to the downstream side by ΔL corresponding to the deviation between the concentration position C and the focal point FP, thereby changing the inter-lens optical path length L to “2F+ΔL”. As a result, the upstream-side focal point of the downstream lens 80b coincides with the concentration position C at which the beam divergence angle is minimized. In this state, the downstream lens 80b can relay the image having the minimum beam divergence angle. By such control, adjustment of the beam divergence angle is realized.

### 2.3 Effect

According to the laser device 2A of the first embodiment, by including the beam divergence angle adjuster 80 and the laser processor 70 that controls the beam divergence angle adjuster 80, it is possible to suppress an increase in the beam divergence angle caused by thermal deformation or the like of the optical element. By suppressing the increase in the beam divergence angle, vignetting of a beam in the exposure apparatus 3 is also suppressed, and the energy loss is also suppressed.

In the above embodiment, the inter-lens optical path length Lr_min at which the beam divergence angle is minimized is a concept including an error in the range of ±10%. The laser processor 70 is simply required to perform control into the error range. Further, in the control of the beam divergence angle adjustment, it is not necessarily required to change the inter-lens optical path length Lr_min at which the beam divergence angle is minimized, and it is simply required to suppress an increase in the beam divergence angle due to a change in the repetition frequency RR. That is, when the repetition frequency RR changes, the laser processor 70 can obtain the above-described effect by changing the inter-lens optical path length L so that the beam divergence angle of the extended pulse laser light PL becomes small.

Further, in the above embodiment, the control of the beam divergence angle adjustment is performed using the table data shown in FIG. 10, but instead of the table data, the control of the beam divergence angle adjustment may be performed by calculation using a function corresponding to the graph shown in FIG. 9.

### 3. Second Embodiment

Next, the laser device according to a second embodiment of the present disclosure will be described. In the following, the laser device according to the second embodiment is substantially the same as the configuration of the laser device 2A according to the first embodiment, except that the duty DC defined by Expression (1) is used instead of the repetition frequency RR in the control of the beam divergence angle adjuster 80. Differences will be described below.

### 3.1 Configuration

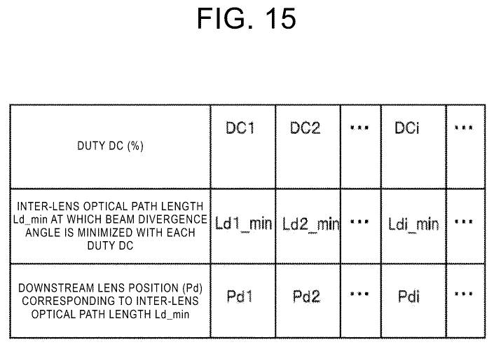

FIG. 15 is an example of the data table to be used by the laser processor 70 of the laser device according to the second embodiment. For each of the plurality of duties DC, a correspondence relationship between the inter-lens optical path length Ld_min at which the beam divergence angle is minimized and the corresponding downstream lens position Pd is recorded. The table data is stored in the memory 70a. The table data shown in FIG. 15 can be obtained by simulation or experiment, similarly to the table data shown in FIG. 10. In the table data, the duty DC is, for example, in a range of 1% to 10%.

In the second embodiment as well, as in the first embodiment, one of the inter-lens optical path length Ld_min and the downstream lens position Pd in the table data shown in FIG. 15 may be stored, and the other may be calculated from a value of the one. Further, since the laser processor 70 is finally controlled based on the downstream lens position Pd, the information stored in the memory 70a may be only the downstream lens position Pd for each duty DC.

### 3.2 Operation

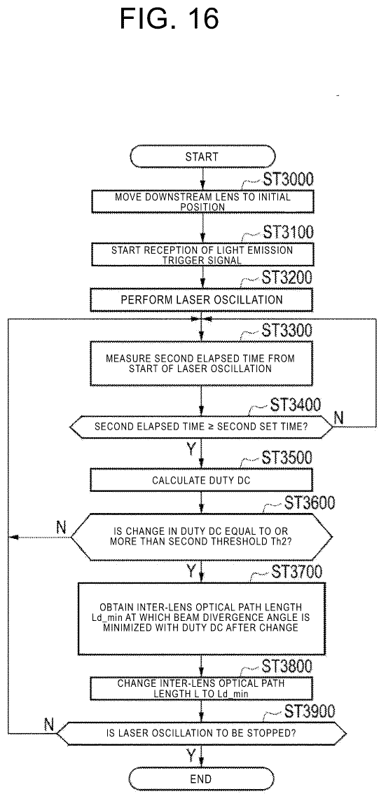

Operation of the laser device of the second embodiment will be described as referring to a flowchart shown in FIG. 16. Similarly to the laser device 2A of the first embodiment shown in FIG. 11, when the control of the beam divergence angle is started, the laser processor 70 first moves the downstream lens 80b to a preset initial position in step ST3000. As shown in FIG. 7 as an example, the initial position is a position where the inter-lens optical path length L is twice the focal length F (2F).

In step ST3100, when reception of the light emission trigger signal from the exposure apparatus 3 is started, the laser processor 70 proceeds to step ST3200 and starts laser oscillation. Laser oscillation is performed every time the light emission trigger signal is received.

In step ST3300, the laser processor 70 measures a second elapsed time since laser oscillation is started.

In step ST3400, the laser processor 70 determines whether or not the second elapsed time is equal to or more than a second set time, returns to step ST3300 while the second elapsed time is less than the second set time (N in step ST3400), and continues measurement of the second elapsed time. On the other hand, when the second elapsed time has reached the second set time or more (Y in step ST3400), the laser processor 70 calculates the duty DC.

The second set time corresponds to the set time Tc associated with Expression (1) above. In calculating the duty DC, when the second elapsed time becomes equal to or more than the second set time, the laser processor 70 counts Np, which is the number of pulses of the pulse laser light PL output within the second elapsed time. Further, the laser processor 70 obtains Np_max, which is the maximum value of the number of pulses that the laser device of the second embodiment can output within the second elapsed time, based on the maximum repetition frequency RR_max that is set in advance and the second elapsed time. The laser processor 70 obtains the duty DC based on Np and Np_max according to Expression (1) of the duty DC. The second set time is, for example, in a range of 45 to 90 seconds.

In step ST3600, the laser processor 70 determines whether or not the change from the previous duty DC is equal to or more than a second threshold Th2. When the determination result is being less than the second threshold Th2 (N in step ST3600), the laser processor 70 returns to step ST3300, and when the determination result is being equal to or more than the second threshold Th2 (Y in step ST3600), the laser processor 70 proceeds to step ST3700.

The reason for setting the second threshold Th2 is similar to the reason for setting the first threshold Th1 of the first embodiment. The second threshold Th2 may be set to a value in a range of 0% to 2%. In order to substantially provide the dead zone, the second threshold Th2 is preferably set to a value larger than 0%. The second threshold Th2 is an example of the “threshold”in the present disclosure.

In step ST3700, the laser processor 70 refers to the table data (see FIG. 15) stored in the memory 70a to obtain the inter-lens optical path length Ld_min at which the beam divergence angle is minimized with the duty DC after the change.

In step ST3800, the laser processor 70 changes the inter-lens optical path length L to the obtained inter-lens optical path length Ld_min. Specifically, the laser processor 70 reads the downstream lens position Pd corresponding to the obtained inter-lens optical path length Ld_min from the table data in the memory 70a. Then, the downstream lens 80b is moved to the read downstream lens position Pd by controlling the optical path length changing mechanism 90. As a result, the inter-lens optical path length L is changed to “Ld_min”.

The laser processor 70 continues the above operation until laser oscillation is stopped (step ST3900).

### 3.3 Effect

The effect of the laser device according to the second embodiment is similar to that of the laser device 2A according to the first embodiment. Depending on the operation of the exposure apparatus 3, it may be possible to appropriately control the beam divergence angle adjuster 80 by using the duty DC rather than the repetition frequency RR. It is preferable that whether the repetition frequency RR or the duty DC is used is appropriately selected according to an actual situation.

### 4. Modification

4.1 First modification

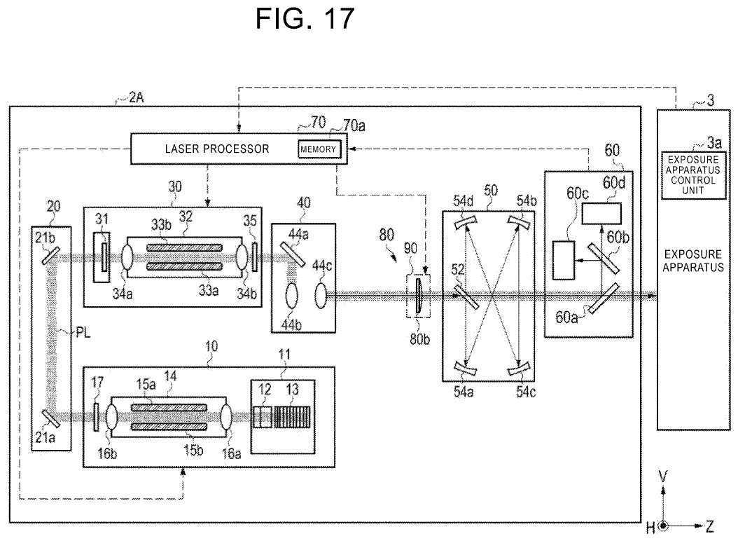

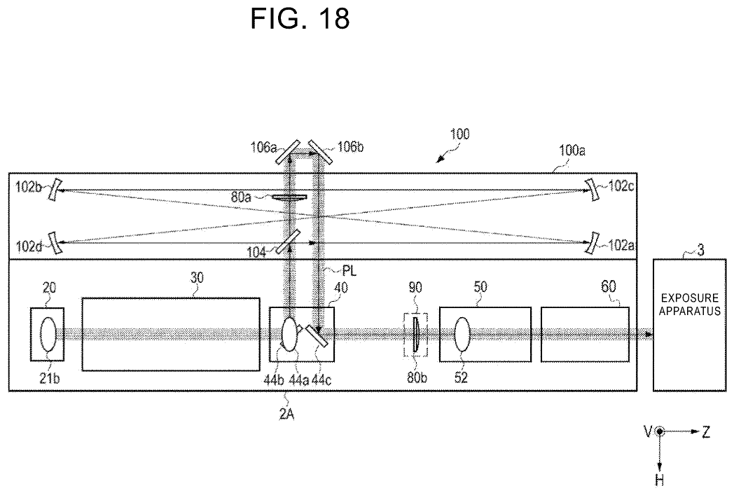

A first modification shown in FIGS. 17 and 18 is an example in which the position of the beam divergence angle adjuster 80 in the laser device 2A of the first embodiment is changed. Specifically, in the first modification, the upstream lens 80a is arranged in the housing 100a of the first OPS 100, and the downstream lens 80b is arranged outside the housing 100a and upstream of the second OPS 50.

The upstream lens 80a is arranged in the housing 100a between the beam splitter 104 and the high reflection mirror 106a. The optical path between the beam splitter 104 and the high reflection mirror 106a is an optical path in the housing 100a and on which the pulse laser light PL whose pulse width is extended after circulating through the delay optical path passes. Therefore, the pulse laser light PL whose pulse width is extended by the first OPS 100 is incident on the upstream lens 80a, and the beam divergence angle adjuster 80 can adjust the beam divergence angle of the pulse laser light PL whose pulse width is extended.

According to the first modification, since the inter-lens optical path length L between the upstream lens 80a and the downstream lens 80b can be set long, the upstream lens 80a and the downstream lens 80b are easily arranged even when the focal lengths F thereof are long. As a lens characteristic, influence of aberration tends to be reduced when the focal length F is long. According to the first modification, it is easy to use lenses each having a relatively less effect of aberration as the upstream lens 80a and the downstream lens 80b.

### 4.2 Second Modification

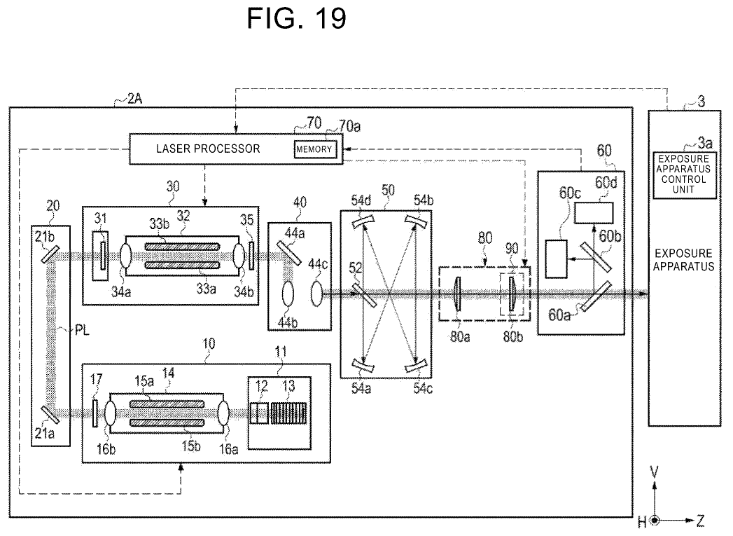

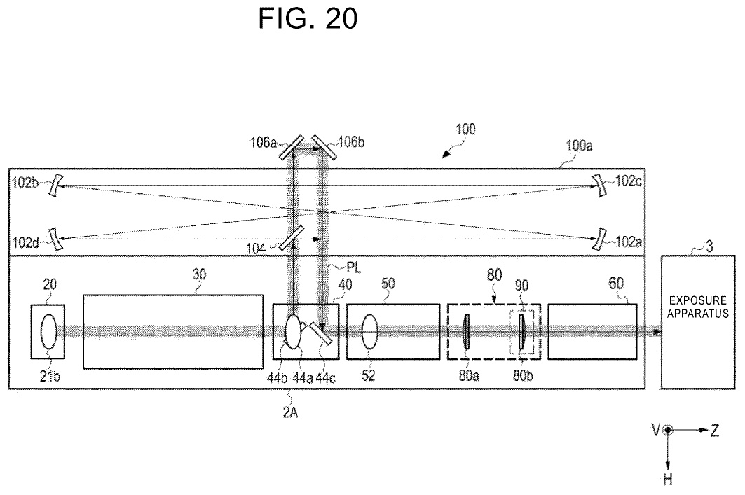

Similarly to the first modification, a second modification shown in FIGS. 19 and 20 is an example in which the position of the beam divergence angle adjuster 80 in the laser device 2A of the first embodiment is changed. Specifically, in the second modification, the beam divergence angle adjuster 80 is arranged downstream of the second OPS 50.

The second modification can be used when a space can be secured downstream of the second OPS 50.

### 4.3 Other Modification

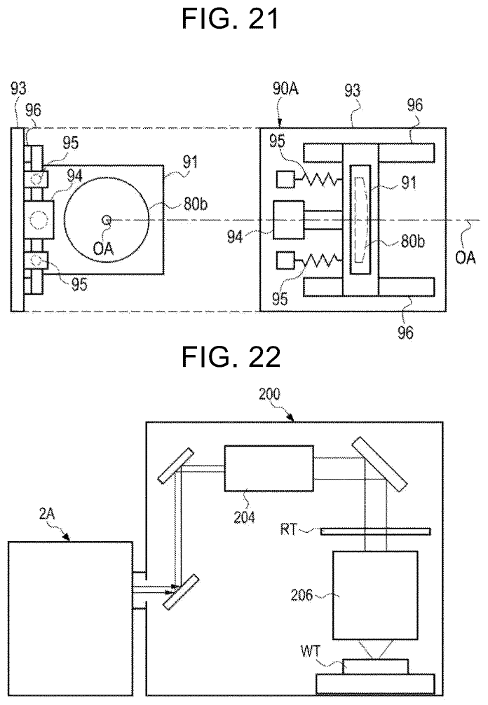

An optical path length changing mechanism 90A shown in FIG. 21 is a modification of the optical path length changing mechanism 90 shown in FIG. 8. The optical path length changing mechanism 90A moves the lens holder 91 by an actuator 94 and a spring 95 instead of the linear stage 92. The actuator 94 is, for example, a solenoid having a plunger that is movable between a protrusion position and a retraction position. The actuator 94 is controlled by the laser processor 70. The actuator 94 is fixed to the pedestal 93, and the plunger abuts to the lens holder 91. When the plunger protrudes, the lens holder 91 is pushed and moved in one direction in the optical axis OA. The spring 95 has an urging force for pulling the lens holder 91 in a direction in which the plunger retracts. Therefore, when the plunger is retracted, the lens holder 91 moves while keeping the contact state with the plunger by the urging force of the spring 95. Various modifications can be made to the configuration of the optical path length changing mechanism, and may be appropriately selected.

Further, in the above embodiments, the optical path length changing mechanism has been described as an aspect in which the position of the downstream lens 80b is changed, but the position of the upstream lens 80a may be changed instead. For example, in the state shown in FIG. 13, by moving the position of the upstream lens 80a to the upstream side, it is possible to realize the state shown in FIG. 14 in which the concentration position C of the pulse laser light PL and the focal point of the downstream lens 80b coincide with each other. Which one of the upstream lens 80a and the downstream lens 80b is to be moved is appropriately selected in consideration of the space for arrangement.

### 5. Electronic Device Manufacturing Method

FIG. 22 schematically shows a configuration example of an exposure apparatus 200. The exposure apparatus 200 includes an illumination optical system 204 and a projection optical system 206. For example, the illumination optical system 204 illuminates a reticle pattern of a reticle (not shown) arranged on a reticle stage RT with the pulse laser light PL incident from the laser device 2A according to the first embodiment. The projection optical system 206 causes the pulse laser light PL transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 200 synchronously translates the reticle stage RT and the workpiece table WT to expose the workpiece to the pulse laser light PL reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure. Here, as the laser device 2A, the laser device according to the second embodiment or the laser device to which each of the various modifications described above is applied may be used.

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.”

What is claimed is:

1. A laser device comprising:
an oscillator configured to output pulse laser light having an ultraviolet wavelength;
an amplifier configured to amplify the pulse laser light;
an optical pulse stretcher including a beam splitter and a plurality of mirrors, and configured to extend a pulse width of the pulse laser light;
a beam divergence angle adjuster including an upstream lens arranged upstream on an optical path of the pulse laser light, a downstream lens arranged downstream of the upstream lens on the optical path, and an optical path length changing mechanism for changing an inter-lens optical path length between the upstream lens and the downstream lens, and configured to adjust a beam divergence angle of the extended pulse laser light; and
a processor configured to control the beam divergence angle adjuster and configured to obtain a repetition frequency or a duty of the pulse laser light, and to change, when the repetition frequency or the duty changes by a preset threshold or more, the inter-lens optical path length so that the beam divergence angle of the extended pulse laser light becomes small in accordance with the repetition frequency or the duty after the change.

2. The laser device according to claim 1,
wherein the amplifier includes a pair of discharge electrodes, and
the processor changes, in control of the beam divergence angle adjuster, the inter-lens optical path length based on a beam divergence angle in a discharge direction of the discharge electrodes.

3. The laser device according to claim 1,
wherein the processor changes the inter-lens optical path length to a value with which the beam divergence angle is minimized in accordance with the repetition frequency or the duty after the change.

4. The laser device according to claim 1,
wherein the processor includes a memory configured to store information related to an inter-lens optical path length at which the beam divergence angle of the extended pulse laser light is minimized as being associated with each of a plurality of the repetition frequencies or a plurality of the duties, and
the processor obtains, from the memory, the information related to the inter-lens optical path length at which the beam divergence angle is minimized in accordance with the repetition frequency or the duty after the change.

5. The laser device according to claim 4,
wherein the information related to the inter-lens optical path length is the inter-lens optical path length or a position of the upstream lens or the downstream lens for providing the inter-lens optical path length.

6. The laser device according to claim 1,
wherein the optical path length changing mechanism changes the inter-lens optical path length by changing a position of the downstream lens.

7. The laser device according to claim 1,
wherein the upstream lens and the downstream lens function as a relay lens that relays, via the downstream lens, a beam spot of the pulse laser light concentrated by the upstream lens.

8. The laser device according to claim 7,
wherein the upstream lens is a plano-convex lens having a convex surface on an incident side thereof, and the downstream lens is a plano-convex lens having a planar surface on an incident side thereof.

9. The laser device according to claim 1,
wherein the optical pulse stretcher includes a first optical pulse stretcher and a second optical pulse stretcher arranged downstream of the first optical pulse stretcher, and
the first optical pulse stretcher has a longer delay optical path than the second optical pulse stretcher.

10. The laser device according to claim 9,
wherein the beam divergence angle adjuster is arranged between the first optical pulse stretcher and the second optical pulse stretcher.

11. The laser device according to claim 9,
wherein the upstream lens is arranged in a housing of the first optical pulse stretcher, and
the downstream lens is arranged outside the housing of the first optical pulse stretcher and upstream of the second optical pulse stretcher.

12. The laser device according to claim 9,
wherein the beam divergence angle adjuster is arranged downstream of the second optical pulse stretcher.

13. An electronic device manufacturing method comprising:
outputting, to an exposure apparatus, pulse laser light output from a laser device; and
exposing a photosensitive substrate to the pulse laser light in the exposure apparatus to manufacture an electronic device,
the laser device including:
an oscillator configured to output the pulse laser light having an ultraviolet wavelength;
an amplifier configured to amplify the pulse laser light;
an optical pulse stretcher including a beam splitter and a plurality of mirrors, and configured to extend a pulse width of the pulse laser light;
a beam divergence angle adjuster including an upstream lens arranged upstream on an optical path of the pulse laser light, a downstream lens arranged downstream of the upstream lens on the optical path, and an optical path length changing mechanism for changing an inter-lens optical path length between the upstream lens and the downstream lens, and configured to adjust a beam divergence angle of the extended pulse laser light; and
a processor configured to control the beam divergence angle adjuster and configured to obtain a repetition frequency or a duty of the pulse laser light, and to change, when the repetition frequency or the duty changes by a preset threshold or more, the inter-lens optical path length so that the beam divergence angle of the extended pulse laser light becomes small in accordance with the repetition frequency or the duty after the change.
